(19) United States
(12) Patent Application Publication
(10) Pub. No.: US 2024/0314727 A1
(43) Pub. Date: Sep. 19, 2024

(54) POSITIONING METHOD, MODEL TRAINING METHOD, AND FIRST DEVICE

(71) Applicant: GUANGDONG OPPO MOBILE TELECOMMUNICATIONS CORP., LTD., Dongguan (CN)

(72) Inventor: Wendong LIU, Dongguan (CN)

(73) Assignee: GUANGDONG OPPO MOBILE TELECOMMUNICATIONS CORP., LTD., Dongguan (CN)

(21) Appl. No.: 18/676,169

(22) Filed: May 28, 2024

Related U.S. Application Data
(63) Continuation of application No. PCT/CN2021/135251, filed on Dec. 3, 2021.

(51) Int. Cl. H04W 64/00; H04L 5/00; H04W 24/10

(52) U.S. Cl. CPC H04W 64/00; H04L 5/0051; H04W 24/10

(57) ABSTRACT

Provided are a positioning method a model training method, and a first device. The positioning method includes: sending, by a first device, measurement information; and receiving by the first device, location information of the first device. The location information is obtained by processing the measurement information based on a positioning model.

### CROSS REFERENCE TO RELATED APPLICATIONS

The present disclosure is a continuation-application of International (PCT) Patent Application No. PCT/CN2021/135251, filed on Dec. 3, 2021, the entire disclosure of which is hereby incorporated by reference in its entirety.

### TECHNICAL FIELD

The present disclosure relates to the field of communication technologies, and in particular, to a positioning method, a model training method, and a first device.

### BACKGROUND

A position of a terminal may be determined by a positioning method. There are many methods for terminal positioning, such as a time measurement-based method and an angle-based method in a NR system. The precision of current positioning methods needs to be improved.

### SUMMARY OF THE DISCLOSURE

According to a first aspect, the embodiments of the present disclosure provide a positioning method. The positioning method includes: sending, by a first device, measurement information; and receiving, by the first device, location information of the first device. The location information is obtained by processing the measurement information based on a positioning model.

According to a second aspect, the embodiments of the present disclosure provide a positioning method. The positioning method includes: receiving, by the second device, measurement information; processing, by the second device, the measurement information based on a positioning model to obtain location information of the first device; and sending, by the second device, the location information of the first device.

According to a third aspect, the embodiments of the present disclosure provide a model training method. The model training method includes: constructing measurement information and location information fed back by multiple first devices into a sample data set; and transfer training the first model by adopting the sample data set to obtain a second model.

According to a fourth aspect, the embodiments of the present disclosure provide a first device. The first device includes a processor and a memory. The memory is configured to store a computer program, the processor is configured to call and run the computer program stored in the memory to execute: sending, by a first device, measurement information; and receiving, by the first device, location information of the first device. The location information is obtained by processing the measurement information based on a positioning model.

### BRIEF DESCRIPTION OF THE DRAWINGS

FIG. 1 is a schematic diagram of an application scenario according to an embodiment of the present disclosure.

FIG. 2 is a schematic diagram of an exemplary neuron structure.

FIG. 3 is a schematic diagram of an exemplary neural network.

FIG. 4 is a schematic diagram of an exemplary convolutional neural network.

FIG. 5 is a schematic diagram of an exemplary basic LSTM unit structure.

FIG. 6 is a schematic diagram of a simple exemplary transfer learning process.

FIG. 7 is a schematic flow chart of a positioning method according to an embodiment of the present disclosure.

FIG. 8 is a schematic diagram of an exemplary positioning method based on deep learning.

FIG. 9 is a schematic flow chart of a positioning method according to another embodiment of the present disclosure.

FIG. 10 is a schematic flow chart of a positioning method according to another embodiment of the present disclosure.

FIG. 11 is a schematic diagram of a two-dimensional coordinate output by a model.

FIG. 12 is a schematic diagram of a three-dimensional coordinate output by a model.

FIG. 13 is a schematic diagram of a location block index output by a model.

FIG. 14 is a schematic diagram of multiple positioning scenarios.

FIG. 15 is a schematic diagram of a measurement feedback.

FIG. 16 is a schematic diagram of a scenario change.

FIG. 17 is a schematic diagram of a positioning model update.

FIG. 18 is a schematic block diagram of a first device according to an embodiment of the present disclosure.

FIG. 19 is a schematic block diagram of a second device according to an embodiment of the present disclosure.

FIG. 20 is a schematic block diagram of a communication device according to an embodiment of the present disclosure.

FIG. 21 is a schematic block diagram of a communication device according to an embodiment of the present disclosure.

FIG. 22 is a schematic block diagram of a chip according to an embodiment of the present disclosure.

FIG. 23 is a schematic block diagram of a communication system according to an embodiment of the present disclosure.

### DETAILED DESCRIPTION

The technical solutions in the embodiments of the present disclosure will be described below with reference to the drawings in the embodiments of the present disclosure.

The technical solutions according to the embodiments of the present disclosure may be applied to various communication systems, such as: a Global System of Mobile communication (GSM) system, a Code Division Multiple Access (CDMA) system, a Wideband Code Division Multiple Access (WCDMA) system, a General Packet Radio Service (GPRS), a Long Term Evolution (LTE) system, an Advanced Long Term Evolution (LTE-A) system, a New Radio (NR) system, an evolution system of a NR system, a LTE-based access to unlicensed spectrum (LTE-U) system, a NR-based access to unlicensed spectrum (NR-U) system, a Non-Terrestrial Network (NTN) system, an Universal Mobile Telecommunication System (UMTS), a Wireless Local Area Network (WLAN), a Wireless Fidelity (Wi-Fi), a 5th-Generation (5G) system or other communication systems, etc.

A traditional communication system supports a limited number of connections and is easy to implement. However, with the development of communication technologies, a mobile communication system will not only support traditional communication, but also support, for example, Device to Device (D2D) communication, Machine to Machine (M2M) communication, Machine Type Communication (MTC), Vehicle to Vehicle (V2V) communication, or Vehicle to everything (V2X) communication, etc. The embodiments of the present disclosure may also be applied to these communication systems.

In a possible implementation, the communication system in the embodiments of the present disclosure may be applied to a Carrier Aggregation (CA) scenario, a Dual Connectivity (DC) scenario, or a Standalone (SA) network deployment scenario.

In a possible implementation, the communication system in the embodiments of the present disclosure may be applied to an unlicensed spectrum. The unlicensed spectrum may also be considered as a shared spectrum. Alternatively, the communication system in the embodiments of the present disclosure may also be applied to a licensed spectrum. The licensed spectrum may also be considered as an unshared spectrum.

The embodiments of the present disclosure describe various embodiments in combination with a network device and a terminal device. The terminal device may also be called a user equipment (UE), an access terminal, a user unit, a user station, a mobile station, a mobile base, a remote station, a remote terminal, a mobile device, a user terminal, a terminal, a wireless communication device, a user agent, or a user device, etc.

The terminal device may be a station (ST) in a WLAN, a cellular phone, a cordless phone, a Session Initiation Protocol (SIP) phone, a Wireless Local Loop (WLL) station, or a Personal Digital Assistant (PDA) devices, a handheld device with wireless communication capabilities, a computing device or another processing device connected to a wireless modem, a vehicle-mounted device, a wearable device, a next-generation communication system such as a terminal device in a NR network, or a terminal device in a future evolved Public Land Mobile Network (PLMN), etc.

In the embodiments of the present disclosure, the terminal device may be deployed on land, including indoor or outdoor, handheld, wearable or vehicle-mounted; may also be deployed on water (such as a ship, etc.); and may also be deployed in air (such as an aircraft, a balloon, and a satellite, etc.).

In the embodiments of the present disclosure, the terminal device may be a mobile phone, a pad, a computer with a wireless transceiver function, a virtual reality (VR) terminal device, or an augmented reality (AR) terminal device, a wireless terminal device in industrial control, a wireless terminal device in self-driving, a wireless terminal device in remote medical, a wireless terminal device in smart grid, a wireless terminal device in transportation safety, a wireless terminal device in smart city, or a wireless terminal device in smart home, etc.

As an example, but not a limitation, in the present embodiment of the present disclosure, the terminal device may also be a wearable device. The wearable device may also be called a wearable smart device, which is a general term for applying wearable technology to intelligently design daily wear and develop wearable devices, such as glasses, gloves, watches, clothing, and shoes, etc. The wearable device is a portable device which may be worn directly on a user's body or integrated into the user's clothing or accessories. The wearable device is not just a hardware device, but may also achieve powerful functions through software support, data interaction, and cloud interaction. A broadly defined wearable smart device includes a full-featured, large-sized device that may achieve complete or partial functions without relying on a smartphone, such as a smart watch or smart glasses; and includes those, such as various types of smart bracelets for physical sign monitoring, or a smart jewelry, etc., only focus on a certain type of application function and need to be used by cooperating with another device such as a smartphone.

In the present embodiment of the present disclosure, the network device may be a device configured to communicate with a mobile device. The network device may be an access point (AP) in WLAN, or a base transceiver station (BTS) in GSM or CDMA, it may also be a NodeB (NB) in WCDMA, an Evolutional Node B (eNB or eNodeB) in LTE, a relay station, an access point, a vehicle-mounted device, a wearable device, an NR network (gNB) in NR network, a network device in a future evolved PLMN network, or a network device in an NTN network, etc.

As an example, but not a limitation, in the embodiments of the present disclosure, the network device may have mobile features, for example, the network device may be a mobile device. In some embodiments, the network device may be a satellite or a balloon station. For example, the satellite may be a low earth orbit (LEO) satellite, a medium earth orbit (MEO) satellite, a geostationary earth orbit (GEO) satellite, or a high elliptical orbit (HEO) satellite, etc. In some embodiments, the network device may also be a base station installed on land, water, etc.

In the present embodiment of the present disclosure, the network device may provide service for a cell, and the terminal device communicates with the network device through transmission resources (for example, frequency domain resources, or spectrum resources) adopted by the cell. The cell may be a cell corresponding to the network device (For example, a base station). The cell may belong to a macro base station or a base station corresponding to a small cell. The small cell referred here may include: a Metro cell, a Micro cell, a Pico cell, a Femto cell, etc. These small cells have the features of small coverage and low transmission power, and are suitable for providing high-rate data transmission services.

FIG. 1 illustrates a communication system 100. The communication system includes a network device 110 and two terminal devices 120. In a possible implementation, the communication system 100 may include multiple network devices 110, and the coverage of each network device 110 may include a different number of terminal devices 120, which is not limited in the present embodiment of the present disclosure.

In a possible implementation, the communication system 100 may also include other network entities such as a Mobility Management Entity (MME) and an Access and Mobility Management Function (AMF), which is not limited in the present embodiment of the present disclosure.

The network device may include an access network device and a core network device. That is, the wireless communication system also includes multiple core networks configured to communicate with the access network device. The access network device may be a long-term evolution (LTE) system, a next radio (NR) (mobile communication system) system or a macro base station of an Evolutionary node B (eNB or e-NodeB) in an authorized auxiliary access long-term evolution (LAA-LTE), a pico base station, an access point (AP), a transmission point (TP) or a new generation Node B (gNodeB), etc.

In the embodiments of the present disclosure, a device with a communication function in a network/system may be called a communication device. Taking the communication system shown in FIG. 1 as an example, the communication device may include a network device and a terminal device with a communication function. The network device and the terminal device may be a specific device in the embodiments of the present disclosure, which will not be described again here. The communication device may also include other devices in the communication system, such as a network controller, a mobility management entity and other network entities, which are not limited in the embodiments of the present disclosure.

The terms “system” and “network” are often used interchangeably herein. The term “and/or” in the present disclosure is just an association relationship that describes related objects, indicating that three relationships may exist. For example, A and/or B may mean: A exists alone, A and B exist simultaneously, and B exists alone. In addition, the character “/” in the present disclosure generally indicates that the related objects are an “or” relationship.

The term “indicate” mentioned in the embodiments of the present disclosure may be a direct indication, an indirect indication, or an association relationship. For example, A indicates B may have the following meanings. It may mean that A directly indicates B, for example, B may be obtained through A. It may also mean that A indirectly indicates B, for example, A indicates C, and B may be obtained through C. It may also mean that there is an associated relationship between A and B.

In the description of the embodiments of the present disclosure, the term “correspondence” may mean that there is a direct correspondence or indirect correspondence between the two, it may also mean that there is an associated relationship between the two, or it may mean instructing and being instructed, configuring, and being configured and other relationships.

To facilitate understanding of the technical solutions of the embodiments of the present disclosure, the relevant technologies of the embodiments of the present disclosure are described below. The following related technologies may be optionally combined with the technical solutions of the embodiments of the present disclosure, and they all belong to the protection scope of the embodiments of the present disclosure.

### 1: Positioning Method in a NR System

In an indoor scenario with severe multipath and non-line-of-sight (NLOS), it is difficult to achieve high-precision positioning. The NR system includes a variety of positioning methods, such as a time measurement-based methods and an angle-based method. The main application scenarios include general indoor and outdoor scenarios, and the precision requirement is about 3 m. 3GPP has also established a positioning enhancement project to meet a decimeter-level positioning requirement in a commercial scenario and an Industrial Internet of Things (IIOT) scenario. Especially in the IIOT scenario, a horizontal positioning precision is required to be less than 0.2 m. However, the classic positioning algorithm based on Time Difference of Arrival (TDOA) uses the method of calculating the user's position by adopting known positions of multiple base stations and a signal's arrival time difference. When a NLOS probability is large and a line-of-sight (LOS) probability is small, the error is very high, thus not able to achieve high-precision positioning.

### 2: Neural Network and Deep Learning

Neural network is a computational model composed of multiple neuron nodes connected to each other. The connections between nodes represent weighted values from an input signal to an output signal, which are called weights. Each node performs a weighted summation of different input signals, and outputs it through a specific activation function.

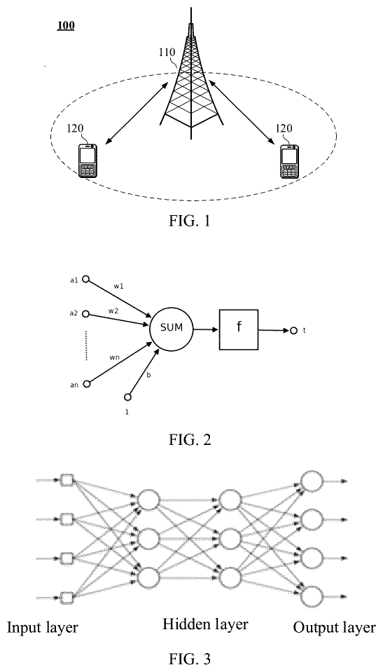

An exemplary neuron structure is shown in FIG. 2. In the neuron, a1, a2 . . . an represent input features, w1, w2 . . . wn represent weight, SUM represents summation, b represents bias coefficient, f represents activation function, and t represents output of the neuron.

A simple exemplary neural network is shown in FIG. 3, which includes an input layer, a hidden layer, and an output layer. Through different connection methods, weights and activation functions of multiple neurons, different outputs may be generated, and then mapping relationship from input to output may be fitted.

Deep learning adopts deep neural network with multiple hidden layers, which greatly improves the network's feature learning ability and may fit a complex nonlinear mapping from input to output. It is widely used in the field of speech and image processing. In addition to deep neural network, with respect to different tasks, deep learning also includes common basic structure such as convolutional neural network (CNN) and recurrent neural network (RNN).

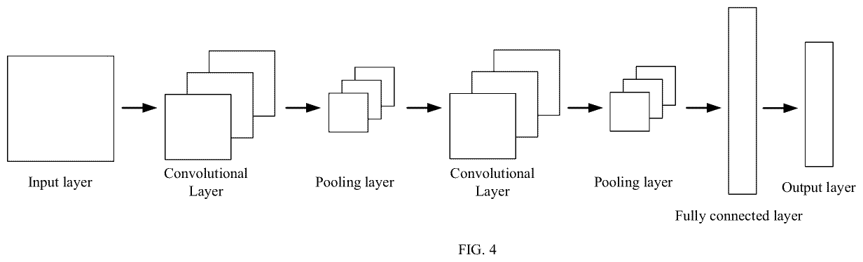

As shown in FIG. 4, the basic structure of an exemplary convolutional neural network may include: an input layer, multiple convolutional layers, multiple pooling layers, a fully connected layer, and an output layer. Each neuron of a convolution kernel in the convolution layer is locally connected to its input, and the pooling layer is introduced to extract a local maximum or average feature of a certain layer, effectively reducing parameters of the network, and mining local features. This enables the convolutional neural network to converge quickly and achieve excellent performance.

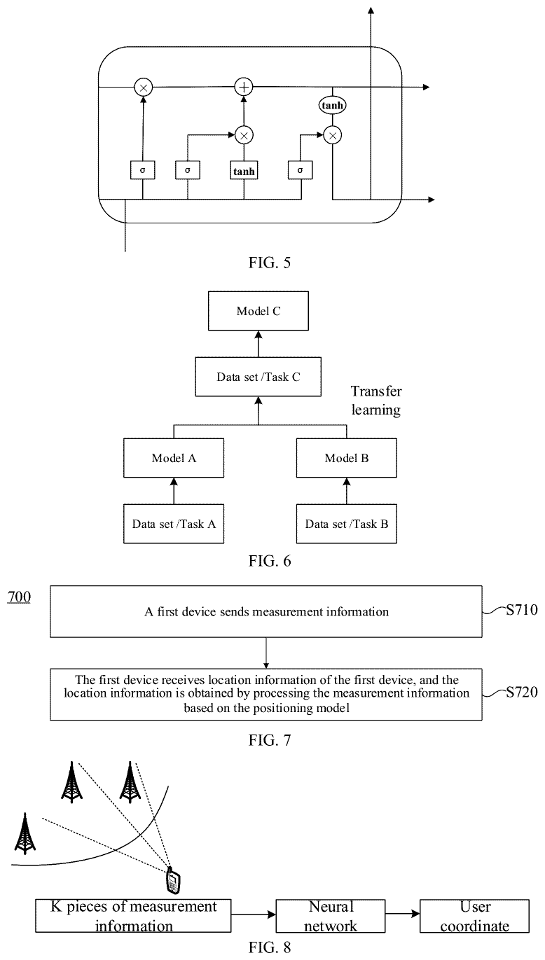

RNN is a neural network that models sequence data. It has achieved remarkable results in the field of natural language processing, such as machine translation, speech recognition and other applications. The specific performance is that the network remembers information of the previous moment and uses it in calculation of the current output. In other words, the nodes between the hidden layers are no longer unconnected but connected, and the input of the hidden layer includes not only the input layer but also includes the output of the hidden layer at the previous moment. RNN may include structures such as Long Short-Term Memory (LSTM) Artificial Neural Network, Gated Recurrent Unit (GRU), etc. FIG. 5 shows an exemplary basic LSTM unit structure. Unlike RNN, which only considers the most recent state, cell state of LSTM will determine which states should be kept and which states should be forgotten, solving the problem of traditional RNN in the long-term memory. In the example of FIG. 5, “+” represents addition, “x” represents multiplication, σ represents sigmoid activation function, and tanh represents hyperbolic tangent activation function.

### 3: Transfer Learning

As an important branch of machine learning, transfer learning may adopt the similarities between data, tasks, or models to apply models and knowledge learned in old fields to new fields. FIG. 6 shows a simple exemplary transfer learning process. Taking different data sets and tasks as an example, model A built by data set/task A and model B built by data set/task B may be integrated through some transfer methods. Then apply the transferred and integrated model to the new data set/task C to complete the application on the data set/task C. Data set A and data set B may be called source domain of transfer learning, and data set C may be called target domain of transfer learning. After transfer learning obtains the initial model based on training in the source domain, the source domain model is trained through sample selection, feature transfer or model fine-tuning, such that the model is also applicable in the target domain, and then the task in the target domain is completed.

On the one hand, the positioning method in the NR system is not able to achieve high-precision positioning when indoor multipath is severe, especially when NLOS is severe. On the other hand, the positioning method based on deep learning rely on collecting a large amount of measured data in a fixed scenario. In the actual deployment process, it is possible that one positioning server serves multiple scenarios at the same time. It is difficult to obtain training sets for multiple scenarios at the same time and then train a positioning model with good generalization. When the channel environment of the positioning scenario changes, it will cause the positioning model to be inappropriate, so the positioning precision is not able to be guaranteed.

FIG. 7 is a schematic flow chart of a positioning method 700 according to an embodiment of the present disclosure. The method may optionally be applied to the system shown in FIG. 1, but is not limited thereto. The method includes at least part of the following operations.

At S710, a first device sends measurement information;

At S720, the first device receives location information of the first device, and the location information is obtained by processing the measurement information based on the positioning model.

For example, the first device sends measurement information to a second device. The measurement information may be measurement information obtained by the first device based on a measured reference signal sent by the network device, for example, sent by the base station. The second device may be a network device or other terminal device besides the first device.

In a possible implementation, the positioning model is a model corresponding to the positioning scenario where the first device is located. For example, in different positioning scenarios, the distribution of at least one environmental variable such as scatterer position, scatterer shape, scatterer surface electromagnetic wave reflection feature, base station number, and base station location may be different. Different positioning models may be set for different positioning scenarios.

In a possible implementation, the method further includes the following operation: the first device detects first signals, and the first signals include a reference signal for positioning. For example, the first device may be a terminal device. The terminal device may detect a reference signal for positioning sent by the network device (such as multiple base stations), and feedback multiple pieces of measurement information to a second device on the network side based on the detected reference signals of the multiple base stations.

In a possible implementation, the first signals include first signals sent by K second devices. For example, the first device may send the measurement information of the K first devices to the second device on the network side, such as a positioning server, based on the reference signals of the K first devices for positioning. The second device, such as a positioning server, may input the received measurement information of the K first devices into a positioning model, such as a neural network model for positioning. The positioning model may output the location information of the first device, such as position coordinate. If a certain position in the positioning scenario corresponding to the positioning model is adopted as the coordinate origin, the position coordinate of the first device may be a relative position coordinate. In addition, the second device, such as the positioning server, may also first determine the corresponding positioning model according to the positioning scenario where the first device is located, and then input the measurement information fed back by the first device into the positioning model corresponding to the first device, thereby obtaining the location information matching the positioning scenario of the first device.

In the embodiments of the present disclosure, artificial intelligence (AI) technology, such as deep learning, may be configured to solve the high-precision positioning problem in the NLOS scenario. An exemplary positioning method based on deep learning is shown in FIG. 8. The user measures channels from K base stations, obtains corresponding K pieces of measurement information, and uses it as input to the neural network to obtain the user's coordinate. The K pieces of measurement information may include complete CIR, or may include measurement information such as RSRP, RSRQ, RSSI, RSRQ dedicated to positioning signal measurement, RSRP dedicated to positioning signal measurement, or one or more types of spatial information, such as an angle of arrival. The neural network needs to be trained and converged by collecting many samples with user coordinate labels before deployment, such that it may complete high-precision positioning. The positioning method may feedback the measured information to the network side through the user (through the first device), and the positioning server on the network side may perform calculations. It may also directly perform AI inference on the user terminal side for a user terminal deployed with AI capabilities, and feedback the positioning result to the network side.

In a possible implementation, the measurement information includes at least one of the following: time domain channel information; frequency domain channel information; measurement indication information.

In a possible implementation, the first device may send time domain channel information, frequency domain channel information or measurement indication information to the second device. The first device may also send any combination of two or more of time domain channel information, frequency domain channel information and measurement indication information.

In a possible implementation, input features of the positioning model in different scenarios may be determined based on one or more of time domain channel information, frequency domain channel information, and measurement indication information.

In a possible implementation, the time domain channel information is determined based on at least one of the following: the number of second devices sending the first signals detected by the first device; the number of time domain sampling points measured by each first device; real part and imaginary part of the time domain channel information measured by the first device; amplitude and phase of the time domain channel information measured by the first device.

In the present embodiment of the present disclosure, the time domain channel information may include a channel impulse response (CIR).

For example, if the first device detects that the number of second devices sending the first signals is K, the number of time domain sampling points of the second device, such as a base station or other network devices, is L. The first device may send KxL pieces of time domain channel information to the second device (such as a positioning server), as KxL input features of the neural network of the positioning model. In the present embodiment of the present disclosure, the first device measures the second device sending the first signals, and the second device serving as the positioning server may be the same device or may be different devices. For example, if the device sending the first signals and the device serving as the positioning server are different devices, the device sending the first signals may be the base station itself, and the device serving as the positioning server may be a device connected to the base station through an optical cable or other backhaul method.

For another example, if the first device detects that the number of second devices sending the first signals is K, the number of time domain sampling points of the second device (such as a base station or other network devices), is L, and the real part and imaginary part of the domain channel information (representing two types of input features) measured by the first device is considered. The first device may send K×L×2 pieces of time domain channel information to the positioning server as K×L×2 input features of the neural network of the positioning model.

For another example, if the first device detects that the number of second devices sending the first signals is K, the number of time domain sampling points of the second device (such as a base station or other network devices) is L, and the amplitude and phase of domain channel information (representing two input features) measured by the first device is considered. The first device may send K×L×2 pieces of time domain channel information to the positioning server as K×L×2 input features of the neural network of the positioning model.

The above description of the relationship between the time domain channel information and the positioning model input features is only an example, but not a limitation. In practical applications, the input features of the positioning model may be flexibly selected based on the scenario corresponding to the positioning model.

In a possible implementation, the frequency domain channel information is determined based on at least one of the following: the number of second devices sending the first signals detected by the first device; the number of frequency domain granularities measured for each first device; real part and imaginary part of the frequency domain channel information measured by the first device; amplitude and phase of the frequency domain channel information measured by the first device.

For example, if the number of second devices sending the first signals detected by the first device is K, the number of frequency domain granularities of the second device (such as a base station or other network devices) is L. The frequency domain granularity may include one or more of subcarrier, resource block (RB), subband level, etc. The first device may send KxL pieces of frequency domain channel information to the positioning server as KxL input features of the neural network of the positioning model.

For another example, if the number of second devices sending the first signals detected by the first device is K, the number of frequency domain granularities of the second device, such as a base station or other network devices, is L. The first device may send KxL frequency domain channel information to the positioning server as KxL input features of the neural network of the positioning model, and consider the real part and imaginary part (representing two types of input features) of the frequency domain channel information measured by the first device. The first device may send K×L×2 pieces of frequency domain channel information to the positioning server as K×L×2 input features of the neural network of the positioning model.

For another example, if the number of second devices sending the first signals detected by the first device is K, the number of frequency domain granularities of the second device, such as a base station or other network devices, is L. The first device may send K×L pieces of frequency domain channel information to the positioning server as K×L input features of the neural network of the positioning model, and consider the amplitude and phase of the frequency domain channel information measured by the first device (representing two input features). The first device may send K×L×2 pieces of frequency domain channel information to the positioning server as K×L×2 input features of the neural network of the positioning model.

The above description of the relationship between the frequency domain channel information and the positioning model input features is only an example, but not a limitation. In practical applications, the input features of the positioning model may be flexibly selected based on the corresponding scenario of the positioning model.

In a possible implementation, the measurement indication information includes at least one of the following: reference Signal Received Power (RSRP); reference Signal Received Quality (RSRQ); received Signal Strength Indicator (RSSI); RSRQ dedicated to positioning signal measurement; and RSRP dedicated for positioning signal measurement.

For example, the first device may send K measurement indication values to the second device. The K measurement indication values include one or more of RSRP, RSRQ, RSSI, RSRQ dedicated to positioning signal measurement, and RSRP dedicated to positioning signal measurement.

In a possible implementation, the location information output by the positioning model includes at least one of the following: two-dimensional coordinate of the first device; three-dimensional coordinate of the first device; and location block index of this first device.

For example, the position coordinate of the first device output by the positioning model may be two-dimensional coordinate (x, y) in the horizontal direction. For another example, the position coordinate of the first device output by the positioning model may be three-dimensional coordinate (x, y, z) including a vertical dimension. For another example, the location information of the first device output by the positioning model may be a location block index in a certain positioning scenario. If the positioning scenario is divided into 16 areas, the location block index of the first device output by the positioning model is 5, indicating that the first device is in the 5th area of the positioning scenario.

In a possible implementation, the different positioning models correspond to different positioning scenarios. For example, the positioning server may input the measurement information fed back by the first device into the positioning model corresponding to the first device based on the positioning model matched by the positioning scenario where the first device is located, thereby obtaining location information matched by the positioning scenario of the first device.

In a possible implementation, structural parameters of the different positioning models are the same. For example, the different positioning models may adopt the same neural network structure and have the same structural parameters, but have different non-structural parameters after being trained. For example, the number of channels, the number of neurons, and activation functions of positioning model A and positioning model B are the same, but weight coefficients after being trained are different.

In a possible implementation, the different positioning models include neural network models with a same interface. For example, the neural network structures adopted by the different positioning models have the same input features, and these positioning models include neural network models with the same interface.

In a possible implementation, the different positioning models have different structural parameters. For example, the different positioning models may adopt different neural network structures, have different structural parameters, and have different non-structural parameters after being trained. For example, convolution kernel size, the number of channels, the number of neurons, and activation functions of positioning model C and positioning model D are different, and weight coefficients after being trained are also different.

In a possible implementation, the different positioning models include neural network models with different interfaces. For example, the neural network structures adopted by the different positioning models have different input features, and these positioning models include neural network models with different interfaces.

In a possible implementation, the structural parameters of the positioning model include at least one of the following: convolution kernel size, convolution kernel type, padding manner, whether to perform batch normalization, depth, the number of channels, the number of neurons and activation function. The structural parameters in the embodiments of the present disclosure are only examples, but not a limitation, and may be flexibly selected according to the specific network structure used in the positioning model.

In a possible implementation, the different positioning models have different weight coefficients and/or bias coefficients. In the embodiments of the present disclosure, the weight coefficient and/or the bias coefficient are non-structural parameters of the positioning model. The neural network structures of different models may be the same or different. The non-structural parameters of different models are different. One or more non-structural parameters may be different, or all non-structural parameters may be different.

In a possible implementation, the method also includes the following operation.

The first device receives a first indication, and the first indication is configured to indicate relevant parameters of measurement information that the first device needs to feedback.

For example, when the first device needs to be positioned, the first device may receive a first indication sent by the positioning server. The first indication may be configured to indicate relevant parameters of measurement information that need to be fed back in a scenario matched by the first device.

In a possible implementation, the relevant parameters of the measurement information include at least one of the following: type of the measurement information; combination of measurement information; and information of multiple second devices needing to be measured.

For example, the first indication may indicate the type of the measurement information that the first device needs to feedback. The first indication being 1 indicates that the time domain channel information needs to be fed back, the first indication being 2 indicates that the frequency domain channel information needs to be fed back, and the first indication being 3 indicates that the frequency domain channel information needs to be fed back. The numerical value of the first indication and its corresponding meaning in the present example are only an example but a not limitations, and may be flexibly changed according to the needs of the positioning model corresponding to different scenarios.

For another example, the first indication may indicate a combination of measurement information that the first device needs to feedback. The first indication being 110 indicates that time domain channel information and the frequency domain channel information need to be fed back, and the first indication being 011 indicates that the time domain channel information and the frequency domain channel information need to be fed back. The first indication being 101 indicates that the time domain channel information and the measurement indication information need to be fed back. The first indication being 101 indicates that time domain channel information, the frequency domain channel information and the measurement indication information need to be fed back. The numerical value of the first indication and its corresponding meaning in the present example are only an example but not a limitation, and may be flexibly changed according to the needs of the positioning model corresponding to different scenarios.

For another example, the first indication may indicate that the first device needs to feedback information of multiple devices (such as base stations) on the network side that need to be measured. In this case, the first device may measure the signals of these base stations, and then feedback the measured complete CIR, frequency domain channel, RSRP, etc. of the base stations to the positioning server according to the requirements of the specific positioning scenario. The positioning server selects required information from the received measurement information and inputs it into the positioning model according to the positioning model matched by the first device.

In a possible implementation, the method also includes the following operation.

The first device receives a second indication, and the second indication is configured to indicate channel measurement configuration for the first device.

For example, if the positioning model needs to be trained or updated, one or more first device may receive a second indication sent by the positioning server. The second indication may be configured to indicate the channel measurement configuration for the first devices. The first devices configured to assist in model training or updating may include multiple terminal devices.

These multiple terminal devices may be different devices from the above-mentioned device that needs to be positioned, or they may be the same device.

In a possible implementation, the channel measurement configuration includes at least one of the following: measurement time length indication; measurement frequency width indication; and measurement cycle indication.

In a possible implementation, the second indication is carried by at least one of the following: Downlink Control Indicator (DCI); signaling dedicated to model update; and signaling dedicated to model training.

For example, a first device receives a DCI from a second device, and the DCI carries a channel measurement configuration for the first device. For another example, the first device receives signaling dedicated to model update from the second device, and the signaling dedicated to model update carries the channel measurement configuration of the first device. For another example, the first device receives signaling dedicated to model training from the second device, and the signaling dedicated to model training carries the channel measurement configuration for the first device.

In a possible implementation, the method also includes the following operation.

The first device performs channel measurement based on the measurement configuration information, in response to receiving the second indication.

The first device feeds back measurement information and location information of the first device based on a model interface corresponding to the positioning scenario.

For example, after receiving the measurement configuration information such as measurement time length indication, measurement frequency width indication, and measurement period indication sent by the second device on the network side, the first device may perform channel measurement based on the measurement configuration information. Then, the first device may feedback the channel measurement information according to the interface of the positioning model corresponding to the scenario in which it is located, and may also feedback the location information of the first device. The feedback location information of the first device may include one or more of two-dimensional coordinate, three-dimensional coordinate, and index block location of the first device.

In a possible implementation, the second indication also includes a positioning model update indication and/or a positioning model training indication.

In a possible implementation, the first device includes at least one of the following: a terminal at a fixed position; a terminal regularly moving; and a terminal capable of obtaining its own location.

In the case of assisted model being trained or updated, the location of the first device may be fixed or readily available. For example, a terminal with a fixed location may report its own fixed coordinate information. For another example, a terminal regularly moving may report coordinate information at a certain time point according to its own movement rules. For another example, the above-mentioned terminal capable of obtaining its own location may include a terminal that obtains and reports its own location through other positioning methods different from the positioning method in the embodiments of the present disclosure. Other positioning methods include but are not limited to visual positioning, traditional positioning methods specified in the NR protocol, etc.

The positioning method according to the embodiments of the present disclosure may improve positioning precision. For example, in a single scenario, the first device's auxiliary information feedback and the positioning model of the network side are configured to improve the positioning precision of the first device. For another example, in multiple scenarios and time changes, the model of the positioning server may be selected and updated according to different positioning scenarios, ensuring that the positioning model may adapt to the scatterer environment in different scenarios, further ensuring the positioning precision of the first device.

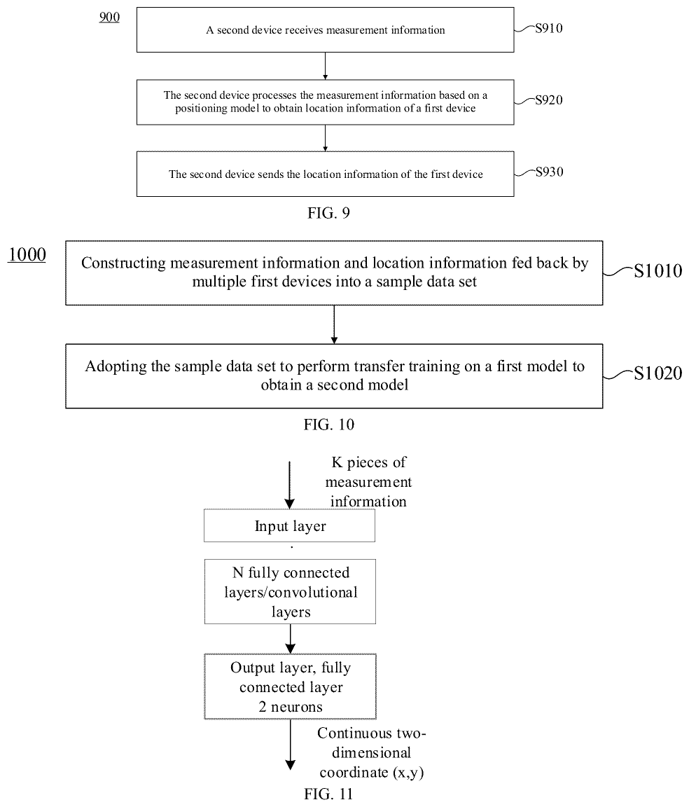

FIG. 9 is a schematic flow chart of a positioning method 900 according to an embodiment of the present disclosure. The method may optionally be applied to the system shown in FIG. 1, but is not limited thereto. The method includes at least part of the following operations.

At S910, a second device receives measurement information.

At S920, the second device processes the measurement information based on a positioning model to obtain location information of a first device.

At S930, the second device sends the location information of the first device.

For example, the second device receives the measurement information sent by the first device, inputs the measurement information into the positioning model corresponding to the positioning scenario of the first device, and obtains the location information of the first device. Then the first device sends the location information of the first device to the first device.

In a possible implementation, the positioning model is a model corresponding to the positioning scenario where the first device is located.

In a possible implementation, the method also includes the following operation.

The second device transmits first signals, and the first signals includes a reference signal for positioning.

In a possible implementation, the measurement information includes at least one of the following: time domain channel information; frequency domain channel information; and measurement indication information.

In a possible implementation, the time domain channel information is determined based on at least one of the following: the number of second devices sending the first signals detected by the first device; the number of time domain sampling points measured by each first device; real part and imaginary part of the time domain channel information measured by the first device; and amplitude and phase of the time domain channel information measured by the first device.

In a possible implementation, the frequency domain channel information is determined based on at least one of the following: the number of second devices sending the first signals detected by the first device; the number of frequency domain granularities measured for each first device; real part and imaginary part of the frequency domain channel information measured by the first device; and amplitude and phase of the frequency domain channel information measured by the first device.

In a possible implementation, the measurement indication information includes at least one of the following: RSRP; RSRQ; RSSI; RSRQ dedicated to positioning signal measurement; and RSRP dedicated to positioning signal measurement.

In a possible implementation, the location information output by the positioning model includes at least one of the following: two-dimensional coordinate of the first device; three-dimensional coordinate of the first device; and location block index of this first device.

In a possible implementation, the different positioning models correspond to different positioning scenarios.

In a possible implementation, structural parameters of the different positioning models are the same.

In a possible implementation, the different positioning models include neural network models with a same interface.

In a possible implementation, the different positioning models have different structural parameters.

In a possible implementation, the different positioning models include neural network models with different interfaces.

In a possible implementation, the structural parameters of the positioning model include at least one of the following: convolution kernel size, convolution kernel type, padding manner, whether to perform batch normalization, depth, the number of channels, the number of neurons and activation function.

In a possible implementation, the different positioning models have different weight coefficients and/or bias coefficients.

In a possible implementation, the method also includes the following operation.

The second device sends a first indication, and the first indication is configured to indicate relevant parameters of the measurement information that the first device needs to feedback.

In a possible implementation, the relevant parameters of the measurement information include at least one of the following: type of the measurement information; combination of measurement information; and information of multiple second devices needing to be measured.

In a possible implementation, the method also includes the following operation.

The second device sends a second indication, and the second indication is configured to indicate channel measurement configuration for the first device.

In a possible implementation, the channel measurement configuration includes at least one of the following: measurement time length indication; measurement frequency width indication; and measurement cycle indication.

In a possible implementation, the second indication is carried by at least one of the following: DCI; signaling dedicated to model update; and signaling dedicated to model training.

In a possible implementation, the method also includes the following operation.

The second device receives measurement information fed back by the first device based on the model interface corresponding to the positioning scenario and coordinate information of the first device.

In a possible implementation, the second indication includes a positioning model update indication and/or a positioning model training indication.

In a possible implementation, the first device includes a terminal at a fixed position and/or a terminal regularly moving.

In a possible implementation, the method also includes the following operation.

The second device constructs measurement information and location information fed back by multiple first devices into a sample data set; and adopt the sample data set to perform transfer training on the first model to obtain the second model.

For example, when model training or model updating is required, the second device sends the second indication to the first device to indicate the first device to feedback the measurement information and its own location information. The measurement information and location information fed back by the first device are constructed as a sample data set. If the model is initially trained, the sample data set may be the initial data set. If the model is updated, the sample data set may be the updated data set.

In a possible implementation, the first model is an initial model, and the second model is a model after transfer training. For example, in the case of initial training of the model, the initial data set is configured to perform transfer training on the initial model to obtain the model after transfer training. The model after transfer training may obtain the location information of the device that needs to be positioned.

In a possible implementation, the first model is a model after a previous transfer training, and the second model is an updated model after a present transfer training. For example, when the model is updated, the updated data set is configured to perform transfer training on the model after a previous transfer training, then the updated model after the present transfer training is obtained. This updated model may be configured to obtain the location information of the device that needs to be located.

In a possible implementation, the transfer training includes the following operation: adjusting a specific layer of the first model, and the specific layer includes one or more layers adjacent to an output layer of the first model. For example, in the case of model update, all layers of the first model may be adjusted, or parameters of one or more layers in the first model adjacent to the output layer may be fine-tuned, thereby achieving rapid model update.

For specific examples of the method 900 executed by the second device in the present embodiment, please refer to the relevant description of the second device in the above-mentioned method 700. For brevity, details will not be described again.

FIG. 10 is a schematic flow chart of a model training method 1000 according to an embodiment of the present disclosure. This method may optionally be applied to the system shown in FIG. 1, but is not limited thereto. The method includes at least part of the following operations. At S1010, constructing measurement information and location information fed back by multiple first devices into a sample data set.

At S1020, adopting the sample data set to perform transfer training on a first model to obtain a second model.

In a possible implementation, the first model is an initial model, and the second model is a model after transfer training.

In a possible implementation, the first model is a model after a previous transfer training, and the second model is an updated model after the present transfer training.

In a possible implementation, the transfer training includes the following operation.

Adjust a specific layer of the first model, and the specific layer including one or more layers adjacent to the output layer of the first model.

In a possible implementation, different second models correspond to different positioning scenarios.

In a possible implementation, structural parameters of different second models are the same.

In a possible implementation, different second models include neural network models with a same interface.

In a possible implementation, different second models have different structural parameters.

In a possible implementation, different second models include neural network models with different interfaces.

In a possible implementation, the structural parameters of the first model and/or the second model include at least one of the following: convolution kernel size, convolution kernel type, padding manner, whether to perform batch normalization, depth, the number of channels, the number of neurons and activation function.

In a possible implementation, different second models have different weight coefficients and/or bias coefficients.

For specific examples of the method 1000 executed by the second device in the present embodiment, please refer to the relevant descriptions of the second device in the above-mentioned method 700 and method 900. For brevity, details are not repeated here.

In a specific example, the embodiments of the present disclosure may provide an AI-based terminal-assisted positioning and model update method for multiple scenarios. By deploying an AI-based positioning network model on the network side, and with the assistance of terminal measurement information feedback, high-precision positioning of the user is achieved. The embodiments of the present disclosure may also consider the model matching selection method in multiple scenarios and the model update method in time-varying scenarios, such that a single positioning server may further ensure the adaptability of the model and positioning precision of the terminal in the scenario when serving the positioning requirements of multiple scenarios.

### Example 1: AI-Based Single-Scenario Terminal-Assisted Positioning Method

The present example provides an AI-based single-scenario terminal-assisted positioning method. For terminals that do not have AI capabilities, the inference of location coordinate is not able to be realized locally on the terminal. Therefore, the acquisition of location coordinate requires terminal-assisted network-side positioning. The process are as follows.

At S1, a terminal detects reference signals configured for positioning sent by K base stations and feeds back the measurement information to a network side.

At S2, a positioning server on the network side receives the measurement information of K base stations fed back by the terminal, inputs a neural network configured for positioning, and outputs location coordinate of the terminal.

At S3: The network side sends the location coordinate of the terminal to the terminal.

The measurement information of the K base stations at S1 and S2 may include but is not limited to the following forms.

A1, time domain channel CIR. For example, K×L×2 time domain channels are adopted as input of the positioning neural network, Lis time domain sampling point measured by each base station, and 2 represents two input channels, which respectively representing real part and imaginary part of the measured time domain channel information, or amplitude and phase of the measured time domain channel information.

A2, frequency domain channel. For example, K×B×2 frequency domain channels are adopted as input of the positioning neural network. B is the number of frequency domain granularities measured by each base station. The granularity may be subcarrier, RB, subband level, etc., and 2 represents two input channels, which respectively represent real part and imaginary part of the measured frequency domain channel information, or amplitude and phase of the measured time domain channel information.

A3, RSRP, RSRQ, RSSI, RSRQ dedicated to positioning signal measurement, RSRP dedicated to positioning signal measurement, and other information indicating the reference signal reception quality. For example, the terminal feeds back K measurement indication values.

A4 includes one or more combined feedback forms of A1, A2, and A3. For example, one possible form is, RSRP, RSRQ, RSSI, RSRQ dedicated to positioning signal measurement, K1 base stations with stronger RSRP dedicated to positioning signal measurement feedback complete A1 or A2 information, the remaining K-K1 base stations only feedback A3 information. The numerical value of K1, as well as the specific feedback parameters configured for AI positioning such as the combined feedback form of A1, A2 and A3, may be configured by the network side through signaling for the user.

The positioning coordinate output by the neural networks at S2 and S3 above may include two-dimensional coordinate (x, y) in the horizontal direction under continuous values, or three-dimensional coordinate (x, y, z) including the vertical dimension, or includes location block index information m under discrete output. And m is an integer 1≤m≤M, M is the number of predefined location block in the scenario. Different neural network outputs require different output layer structures of the neural network configured for AI positioning in S2.

As shown in FIG. 11, K pieces of measurement information are input into the input layer of the model, and after processing by N fully connected and/or convolutional layers, the output layer from the model (in one example, the output layer may be a fully connected layer, with 2 neurons) outputs continuous two-dimensional coordinate (x, y).

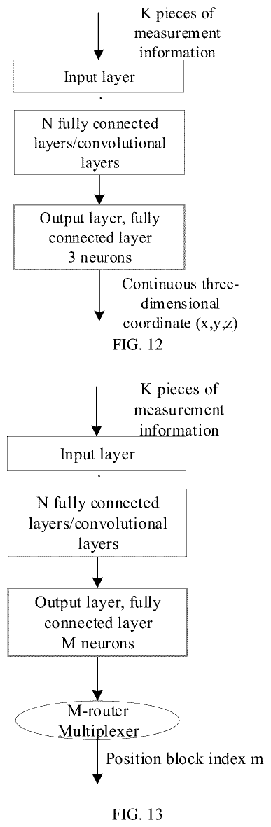

As shown in FIG. 12, K pieces of measurement information are input to the input layer of the model, and after processing by N fully connected and/or convolutional layers, from the output layer of the model (in one example, the output layer may be a fully connected layer, with 3 neurons) outputs continuous three-dimensional coordinate output (x, y, z).

As shown in FIG. 13, K pieces of measurement information are input to the input layer of the model, and after processing by N fully connected and/or convolutional layers, from the output layer of the model (in one example, the output layer may be a fully connected layer, with M neurons) outputs M results, and the discrete position block index m is selected through the M-router Multiplexer.

The output of the above continuous two-dimensional coordinate or three-dimensional coordinate requires the number of neurons in the output layer of the neural network to be 2 and 3 respectively. The output of the discrete position index block requires the number of neurons in the output layer of the neural network to be M, adopting the sigmoid or softmax activation function, and selecting the index corresponding to the maximum value among the M output results through the M-router Multiplexer. Other hidden layer of the neural network includes but are not limited to using architectures such as Deep Neural Network (DNN), CNN, RNN, LSTM, GRU or self-attention mechanism. The present example does not impose further restrictions on the specific structure and parameters of the network.

### Example 2: AI-based multi-scenario terminal-assisted positioning method

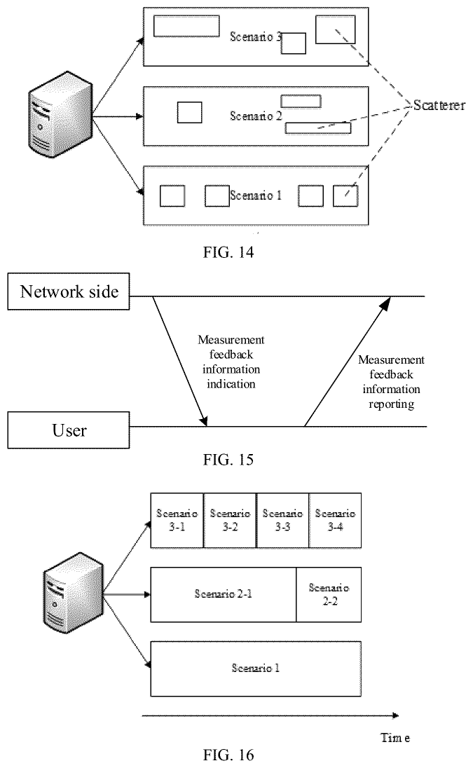

The present example further provides a terminal-assisted positioning method in multiple scenarios based on Example 1. Multiple scenarios in the present example may include positioning scenarios that share a server. For example, positioning scenarios with large differences in the distribution of environmental variables such as the location of scatterers in indoor spaces, electromagnetic wave reflection features of the scatterers' surfaces, the number, or locations of K base stations, etc. in different buildings, rooms, and factories are as shown in FIG. 14.

Scenario 1, scenario 2, and scenario 3 share a positioning server, and the scatterers are distributed differently in each scenario. Therefore, for different scenarios, to ensure the precision requirements of the positioning neural network model in the positioning server in multiple scenarios and meet positioning requirements for multiple scenarios, it is necessary to save positioning models for different scenarios.

The positioning models of the different scenarios are model 1, model 2, and model 3 respectively. Model 1 corresponds to scenario 1, model 2 corresponds to scenario 2, and model 3 corresponds to scenario 3. The relationship between these positioning models may include the following situations.

B1, Model 1, Model 2 and Model 3 respectively adopt the same neural network interface, that is, measurement information feedback, but adopt different neural network models to adapt to different scenarios. The different neural network models may be further classified as follows.

B1.1, multiple models adopt the same structure, but the non-structural parameters are inconsistent. For example, Model 1, Model 2, and Model 3 all adopt CNN models, and the structural parameters, such as the convolution kernel size, convolution kernel type, padding manner, whether to perform batch normalization, depth, the number of channels, the number of neurons and activation function, etc., of the network remain consistent, but the weight coefficients and bias coefficients of the network are unequal.

B1.2, multiple models adopt different structures. For example, Model 1, Model 2, and Model 3 adopt different structural models, such as DNN, CNN and LSTM respectively.

B2, Model 1, Model 2 and Model 3 respectively adopt different neural network interfaces, that is, the required forms of measurement information feedback are different. In some embodiments, including A1 to A4 in Example 1, different number of K base stations in each scenario result in different dimensions of the feedback of the same type of the measurement information, which may also include different feedback forms of A1 to A4 in Example 1. When the neural network interfaces are different, the model structures and parameters of the neural network are also different.

For AI models in different scenarios, they may be pre-trained by collecting data in the corresponding scenarios to form a training set. During the deployment process, users in different scenarios need to match the models corresponding to the scenarios. Therefore, as shown in FIG. 15, the network side needs to indicate the type of the measurement information fed back by the user (the user's terminal) through downlink signaling (such as measurement feedback information indication), and the user reports the measurement feedback information.

The downlink signaling indicates the type of the measurement information fed back by the user, which may include at least two types of indication methods.

C1, this indication directly indicates the type of the measurement information and its combination method. The type of the measurement information and its combination method are known in advance by both the network side and the terminal.

C2, this indication only indicates the information of all K base stations that need to be measured and fed back. For example, the indication will indicate whether all K base stations measure and feedback complete CIR and frequency domain channel reporting, or whether only RSRP reporting is required, without directly indicating the combination feedback by the required type of the measurement information. How the positioning server on the network side combines the measurement feedback information depends on the input interface of the neural network model adopted.

### Example 3: AI-Based Multi-Scenario Terminal-Assisted Positioning Model Update Method

The present example proposes an AI-based multi-scenario terminal-assisted positioning model update method. As shown in FIG. 16, environmental variables such as scatterer position in scenario 1 remain fixed for a long time, environmental variables in scenario 2 change slowly (scenario 2-1 changes to scenario 2-2), and environmental variables in scenario 3 changes rapidly (scenario 3-1 changes to scenario 3-2, then changes to scenario 3-3, and then changes to scenario 3-4). Therefore, it is necessary to update the positioning model according to changing scenarios.

Considering that the model is deployed on the positioning server on the network side, if the scenario changes, the network side needs to obtain updated channel measurement information as model input and user coordinates as labels. Therefore, when the model needs to be updated, the terminal coordinate position of the feedback channel measurement information needs to be known by the network side. In the present example, a terminal device whose coordinate position is known when the model is updated is deployed in the scenario and is called the first terminal; a terminal that does not report the coordinate position when the network positioning model is updated is called the second terminal.

The coordinate position of the first terminal may be fixed, for example, a terminal device fixed on a production line in a factory. The first terminal may also be a terminal regularly moving device, for example, a terminal device that moves regularly horizontally or vertically on a certain production line in a factory. The first terminal may also be a terminal device that includes other auxiliary positioning means, such as machine vision positioning and other methods. The second terminal is generally a terminal device whose coordinate position of the user is unknown.

The updating method of the network-side positioning model includes the following operations.

At S11, the network device, such as the positioning server, sends a positioning model update indication to the first terminal. The positioning model update indication may be carried through DCI or another downlink signaling dedicated to model update. The positioning model update indication may include channel measurement configuration for the terminal, for example, including measurement parameter information such as measurement time length indication, measurement frequency width indication, and measurement period indication.

At S12, after receiving the model update indication, the first terminal performs channel measurement based on the measurement configuration information such as the measurement time length indication, the measurement frequency width indication, and the measurement period indication.

At S13, the first terminal performs channel measurement information feedback based on the model interface in the scenario, and at the same time, feeds back the coordinate information of the first terminal.

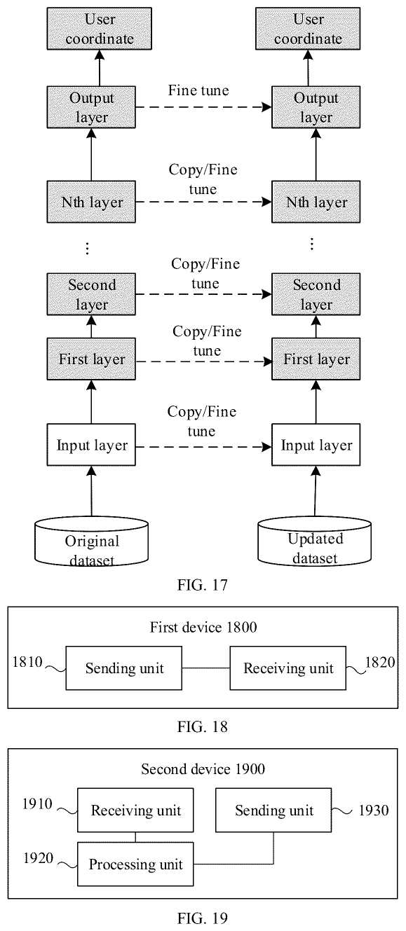

At S14, the network side constructs channel measurement information feedback and coordinate information of multiple first terminals into an updated data set, and performs transfer training on the updated data set based on the original positioning model. The model transfer training in S14, as shown in FIG. 17, may update and fine-tune all layers of the network of the positioning model, or only update and fine-tune a specific layer. The specific layer generally refers to one or more network layers close to the output layer, for example, layer 1 to layer N close to the input layer.

The original positioning model in S14 may be the positioning model continuously used in the previous scenario, or it may be a pre-trained model with better generalization performance. The model parameters may be saved on the positioning server and adopted as the initial model for transfer training every time when the scenario changes and the model is updated.

The embodiments of the present disclosure provide the AI-based terminal-assisted positioning and model update method suitable for multiple scenarios. In the single scenario, the terminal's positioning precision may be improved by adopting terminal auxiliary information feedback and network-side AI positioning model. In the multiple scenarios and time changes, the positioning server model may be selected and updated according to different positioning scenarios to ensure that the positioning model may adapt to the scatterer environment in different scenarios and further ensure the terminal positioning precision.

FIG. 18 is a schematic block diagram of a first device 1800 according to an embodiment of the present disclosure. The first device 1800 may include a sending unit 1810 and a receiving unit 1820.

The sending unit 1810 is configured to send measurement information.

The receiving unit 1820 is configured to receive location information of the first device, and the location information is obtained by processing the measurement information based on the positioning model.

In a possible implementation, the positioning model is a model corresponding to the positioning scenario where the first device is located.

In a possible implementation, the device also includes a processing unit.

The processing unit is configured to detect first signals, and the first signals include a reference signal for positioning.

In a possible implementation, the first signals include first signals sent by K second devices.

In a possible implementation, the measurement information includes at least one of the following: time domain channel information; frequency domain channel information; and measurement indication information.

In a possible implementation, the time domain channel information is determined based on at least one of the following: the number of second devices sending the first signals detected by the first device; the number of time domain sampling points measured by each first device; real part and imaginary part of the time domain channel information measured by the first device; and amplitude and phase of the time domain channel information measured by the first device.

In a possible implementation, the frequency domain channel information is determined based on at least one of the following: the number of second devices sending the first signals detected by the first device; the number of frequency domain granularities measured for each first device; real part and imaginary part of the frequency domain channel information measured by the first device; and amplitude and phase of the frequency domain channel information measured by the first device.

In a possible implementation, the measurement indication information includes at least one of the following: RSRP; RSRQ; RSSI; RSRQ dedicated to positioning signal measurement; and RSRP dedicated to positioning signal measurement.

In a possible implementation, the location information output by the positioning model includes at least one of the following: two-dimensional coordinate of the first device; three-dimensional coordinate of the first device; and location block index of this first device.

In a possible implementation, the different positioning models correspond to different positioning scenarios.

In a possible implementation, structural parameters of the different positioning models are the same.

In a possible implementation, the different positioning models include neural network models with a same interface.

In a possible implementation, the different positioning models have different structural parameters.

In a possible implementation, the different positioning models include neural network models with different interfaces.

In a possible implementation, the structural parameters of the positioning model include at least one of the following: convolution kernel size, convolution kernel type, padding manner, whether to perform batch normalization, depth, the number of channels, the number of neurons and activation function.

In a possible implementation, the different positioning models have different weight coefficients and/or bias coefficients.

In a possible implementation, the receiving unit is further configured to receive a first indication, and the first indication is configured to indicate relevant parameters of the measurement information that the first device needs to feedback.

In a possible implementation, the relevant parameters of the measurement information include at least one of the following: type of the measurement information; combination of measurement information; and information of multiple second devices needing to be measured.

In a possible implementation, the receiving unit is further configured to receive a second indication, and the second indication is configured to indicate channel measurement configuration for the first device.

In a possible implementation, the channel measurement configuration includes at least one of the following: measurement time length indication; measurement frequency width indication; and measurement cycle indication.

In a possible implementation, the second indication is carried by at least one of the following: DCI; signaling dedicated to model updates; and signaling dedicated to model training.

In a possible implementation, the receiving unit is also configured to perform channel measurement based on the measurement configuration information when receiving the second indication.

The sending unit is also configured to feedback the measurement information and the location information of the first device based on the model interface corresponding to the positioning scenario.

In a possible implementation, the second indication also includes a positioning model update indication and/or a positioning model training indication.

In a possible implementation, the first device includes at least one of the following: a terminal at a fixed position; a terminal regularly moving; a terminal capable of obtaining its own location.

In a possible implementation, the first device may include a terminal device.

The first device 1800 in the embodiments of the present disclosure may implement the corresponding functions of the first device in the aforementioned method 700. For the corresponding processes, functions, implementation methods and beneficial effects of each module (sub-module, unit, or component, etc.) of the first device 1800, please refer to the corresponding description in the above method embodiments, and will not be described again here. The functions described for each module (sub-module, unit, or component, etc.) of the first device 1800 in the application embodiment may be implemented by different modules (sub-module, unit, or component, etc.), or may be implemented by the same module (submodule, unit, or component, etc.).

FIG. 19 is a schematic block diagram of a second device 1900 according to an embodiment of the present disclosure.

The second device 1900 may include a receiving unit 1910, a processing unit 1920 and a sending unit 1930.

The receiving unit 1910 is configured to receive measurement information.

The processing unit 1920 is configured to process the measurement information based on a positioning model to obtain location information of a first device.

The sending unit 1930 is configured to send the location information of the first device.

In a possible implementation, the positioning model is a model corresponding to the positioning scenario where the first device is located.

In a possible implementation, the sending unit is also configured to send first signals, and the first signals include a reference signal configured for positioning.

In a possible implementation, the measurement information includes at least one of the following: time domain channel information; frequency domain channel information; and measurement indication information.

In a possible implementation, the time domain channel information is determined based on at least one of the following: the number of second devices sending the first signals detected by the first device; the number of time domain sampling points measured by each first device; real part and imaginary part of the time domain channel information measured by the first device; and amplitude and phase of the time domain channel information measured by the first device.

In a possible implementation, the frequency domain channel information is determined based on at least one of the following: the number of second devices sending the first signals detected by the first device; the number of frequency domain granularities measured for each first device; real part and imaginary part of the frequency domain channel information measured by the first device; and amplitude and phase of the frequency domain channel information measured by the first device.

In a possible implementation, the measurement indication information includes at least one of the following: RSRP; RSRQ; RSSI; RSRQ dedicated to positioning signal measurement; and RSRP dedicated to positioning signal measurement.

In a possible implementation, the location information output by the positioning model includes at least one of the following: two-dimensional coordinate of the first device; three-dimensional coordinate of the first device; and location block index of the first device.

In a possible implementation, the different positioning models correspond to different positioning scenarios.

In a possible implementation, structural parameters of the different positioning models are the same.

In a possible implementation, the different positioning models include neural network models with a same interface.

In a possible implementation, the different positioning models have different structural parameters.

In a possible implementation, the different positioning models include neural network models with different interfaces.

In a possible implementation, the structural parameters of the positioning model include at least one of the following: convolution kernel size, convolution kernel type, padding manner, whether to perform batch normalization, depth, the number of channels, the number of neurons and activation function.

In a possible implementation, the different positioning models have different weight coefficients and/or bias coefficients.

In a possible implementation, the sending unit is further configured to send a first indication, and the first indication is configured to indicate relevant parameters of the measurement information that the first device needs to feedback.

In a possible implementation, the relevant parameters of the measurement information include at least one of the following: type of the measurement information; combination of measurement information; and information of multiple second devices needing to be measured.

In a possible implementation, the sending unit is further configured to send a second indication, and the second indication is configured to indicate channel measurement configuration for the first device.

In a possible implementation, the channel measurement configuration includes at least one of the following: measurement time length indication; measurement frequency width indication; and measurement cycle indication.

In a possible implementation, the second indication is carried by at least one of the following: DCI; signaling dedicated to model update; and signaling dedicated to model training.

In a possible implementation, the receiving unit is further configured to receive measurement information fed back by the first device based on a model interface corresponding to the positioning scenario and location information of the first device.

In a possible implementation, the second indication includes a positioning model update indication and/or a positioning model training indication.

In a possible implementation, the first device includes a terminal at a fixed position and/or a terminal regularly moving.

In a possible implementation, the device also includes a processing unit.

The processing unit is also configured to construct measurement information and location information fed back by multiple first devices into a sample data set; adopt the sample data set to perform transfer training on the first model to obtain a second model.

In a possible implementation, the first model is an initial model, and the second model is a model after transfer training.

In a possible implementation, the first model is a model after a previous transfer training, and the second model is an updated model after the present transfer training.

In a possible implementation, the processing unit performing the transfer training includes the following operation: adjusting a specific layer of the first model, and the specific layer includes one or more layers adjacent to an output layer of the first model.

In a possible implementation, the second device may include a network device.

The second device 1900 in the embodiments of the present disclosure may implement the corresponding functions of the second device in the aforementioned method 900. For the corresponding processes, functions, implementation methods and beneficial effects of each module (sub-module, unit, or component, etc.) of the second device 1900, please refer to the corresponding description in the above method embodiment, and will not be described again here. The functions described for each module (sub-module, unit, or component, etc.) in the second device 1900 of the application embodiment may be implemented by different modules (sub-module, unit, or component, etc.), or may be implemented by the same module (submodule, unit, or component, etc.).

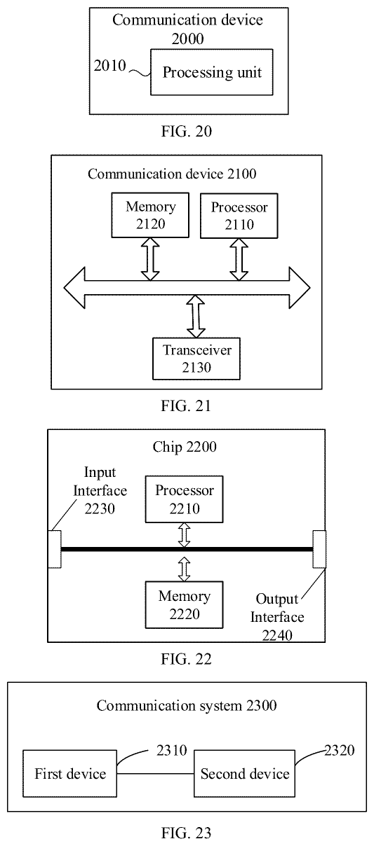

FIG. 20 is a schematic block diagram of a communication device 2000 according to an embodiment of the present disclosure. The communication device 2000 may include a processing unit 2010.

The processing unit 2010 is configured to construct measurement information and location information fed back by multiple first devices into a sample data set; and adopt the sample data set to perform transfer training on the first model to obtain a second model.

In a possible implementation, the first model is an initial model, and the second model is a model after transfer training.

In a possible implementation, the first model is the model after a previous transfer training, and the second model is the updated model after the present transfer training.

In a possible implementation, the processing unit performing the transfer training includes the following operation: adjusting a specific layer of the first model, and the specific layer includes one or more layers adjacent to an output layer of the first model.

In a possible implementation, different second models correspond to different positioning scenarios.

In a possible implementation, structural parameters of different second models are the same.

In a possible implementation, different second models include neural network models with a same interface.

In a possible implementation, different second models have different structural parameters.

In a possible implementation, different second models include neural network models with different interfaces.

In a possible implementation, the structural parameters of the second model include at least one of the following: convolution kernel size, convolution kernel type, padding manner, whether to perform batch normalization, depth, the number of channels, the number of neurons and activation function.

In a possible implementation, different second models have different weight coefficients and/or bias coefficients.

In a possible implementation, the communication device may include a terminal device and/or a network device.

The communication device 2000 in the embodiments of the present disclosure may implement the corresponding functions of the communication device in the aforementioned method 1000. For the corresponding processes, functions, implementation methods and beneficial effects of each module (sub-module, unit, or component, etc.) of the communication device 2000, please refer to the corresponding description in the above method embodiments, and will not be described again here. The functions described with respect to each module (sub-module, unit, or component, etc.) of the communication device 2000 according to the embodiment of the present disclosure may be implemented by different modules (sub-module, unit, or component, etc.), or may be implemented by the same module (submodule, unit, or component, etc.).

FIG. 21 is a schematic structural diagram of a communication device 2100 according to an embodiment of the present disclosure. The communication device 2100 includes a processor 2110, and the processor 2110 may call and run a computer program from a memory, such that the communication device 2100 implements the methods in the embodiments of the present disclosure.

In a possible implementation, the communication device 2100 may also include a memory 2120. The processor 2110 may call and run the computer program from the memory 2120, such that the communication device 2000 implements the methods in the embodiments of the present disclosure.

The memory 2120 may be a separate device independent of the processor 2110, or may be integrated into the processor 2110.

In a possible implementation, the communication device 2100 may also include a transceiver 2130, and the processor 2110 may control the transceiver 2130 to communicate with other devices. In some embodiments, the communication device 2100 may send information or data to, or receive data or information from, other devices.

The transceiver 2130 may include a transmitter and a receiver. The transceiver 2130 may further include an antenna, and the number of antennas may be one or more.

In a possible implementation, the communication device 2100 may be the first device 1800 in the embodiments of the present disclosure, and the communication device 2100 may implement the corresponding processes implemented by the first device in each method of the embodiments of the present disclosure. For brevity, it will not be repeated here again.

In a possible implementation, the communication device 2100 may be the second device 1900 in the embodiments of the present disclosure, and the communication device 2100 may implement the corresponding processes implemented by the second device in the various methods according to the embodiments of the present disclosure. For brevity, it will not be repeated here again.

In a possible implementation, the communication device 2100 may be the communication device 2000 in the embodiments of the present disclosure, and the communication device 2100 may implement the corresponding processes implemented by the communication device in the various methods according to the embodiments of the present disclosure. For brevity, it will not be repeated here again.

FIG. 22 is a schematic structural diagram of a chip 2200 according to an embodiment of the present disclosure. The chip 2200 includes a processor 2210, and the processor 2210 may call and run a computer program from the memory to implement the methods in the embodiments of the present disclosure.

In a possible implementation, the chip 2200 may also include a memory 2220. The processor 2210 may call and run the computer program from the memory 2220 to implement the methods executed by the first device 1800, the second device 1900 or the communication device 2000 in the embodiments of the present disclosure.

The memory 2220 may be a separate device independent of the processor 2210, or may be integrated into the processor 2210.

In a possible implementation, the chip 2200 may also include an input interface 2230. The processor 2210 may control the input interface 2230 to communicate with other devices or chips. In some embodiments, the input interface 2230 may obtain information or data sent by other devices or chips.

In a possible implementation, the chip 2200 may also include an output interface 2240. The processor 2210 may control the output interface 2240 to communicate with other devices or chips. In some embodiments, output interface 2240 may output information or data to other devices or chips.

In a possible implementation, the chip may be applied to the first device 1800 in the embodiments of the present disclosure, and the chip may implement the corresponding processes implemented by the first device in the various methods of the embodiments of the present disclosure. For brevity, it will not be repeated here again.

In a possible implementation, the chip may be applied to the second device 1900 in the embodiments of the present disclosure, and the chip may implement the corresponding processes implemented by the second device in the various methods of the embodiments of the present disclosure. For brevity, it will not be repeated here again.

In a possible implementation, the chip may be applied to the communication device 2000 in the embodiments of the present disclosure, and the chip may implement the corresponding processes implemented by the communication device in each method of the embodiments of the present disclosure. For brevity, it will not be repeated here again.

The chips applied to the first device 1800, the second device 1900 or the communication device 2000 may be the same chip or different chips.

The chips mentioned in the embodiments of the present disclosure may also be called system-on-chip, system-on-a-chip etc.

The processor mentioned above may be a general-purpose processor, a digital signal processor (DSP), a field programmable gate array (FPGA), an application specific integrated circuit (ASIC), or other programmable logic devices, transistor logic devices, discrete hardware components, etc. The above-mentioned general processor may be a microprocessor or any conventional processor.

The memory mentioned above may be volatile memory or non-volatile memory, or may include both volatile and non-volatile memory. The non-volatile memory may be read-only memory (ROM), programmable ROM (PROM), erasable PROM (EPROM), electrically EPROM (EEPROM) or flash memory. The volatile memory may be random access memory (RAM).

The above memory is illustrative but not restrictive. For example, the memory in the embodiments of the present disclosure may also be static RAM (SRAM), dynamic RAM (DRAM), Synchronous DRAM (SDRAM), double data rate SDRAM (DDR SDRAM), enhanced SDRAM (ESDRAM), synch link DRAM (SLDRAM) and direct Rambus RAM (DR RAM) and so on. That is, memories in the embodiments of the present disclosure are intended to include, but are not limited to, these and any other suitable types of memories.

FIG. 23 is a schematic block diagram of a communication system 2300 according to an embodiment of the present disclosure.

The communication system 2300 includes a first device 2310 and a second device 2320.

The first device 2310 is configured to send measurement information; receive location information of the first device, and the location information is obtained by processing the measurement information based on the positioning model.

The second device 2320 is configured to receive the measurement information. The second device processes the measurement information based on the positioning model to obtain the location information of the first device. The second device sends the location information of the first device.

The first device 2310 may be configured to implement the corresponding functions implemented by the first device in the above method 700, and the second device 2320 may be configured to implement the corresponding functions implemented by the second device in the above method 900. For brevity, it will not be repeated here again.

In a possible implementation, the communication system 2300 may also include a communication device for constructing the measurement information and location information fed back by multiple first devices into a sample data set; adopting the sample data set to perform transfer training on the first positioning model to obtain the second positioning model. The communication device may be an independent device, or may be provided in the first device and/or the second device. The communication device may be configured to implement the corresponding functions implemented by the communication device in the above method 1000. For brevity, it will not be repeated here again.

In the above embodiments, it may be implemented in whole or in part by software, hardware, firmware, or any combination thereof. When implemented by software, it may be implemented in whole or in part in the form of a computer program product. The computer program product includes one or more computer instructions. When the computer program instructions are loaded and executed on a computer, the processes, or functions according to the embodiments of the present disclosure are generated in whole or in part. The computer may be a general-purpose computer, a special purpose computer, a computer network, or other programmable device. The computer instructions may be stored in or transmitted from one computer-readable storage medium to another computer-readable storage medium. For example, the computer instructions may be transmitted over a wired connection from a website, computer, server, or data center (such as coaxial cable, optical fiber, Digital Subscriber Line (DSL)) or wireless (such as infrared, wireless, microwave, etc.) means to transmit to another website, computer, server, or data center. The computer-readable storage medium may be any available medium that may be accessed by a computer or a data storage device such as a server or data center integrated with one or more available media. The available media may be magnetic media (e.g., floppy disk, hard disk, magnetic tape), optical media (e.g., DVD), or semiconductor media (e.g., solid state disk (SSD)), etc.

In the various embodiments of the present disclosure, the value of the sequence numbers of the above-mentioned processes does not mean the order of execution. The execution order of each process should be determined by its functions and internal logic, and should not be used in the embodiments of the present disclosure. The implementation process constitutes any limitation.

Those skilled in the art may clearly understand that for the convenience and simplicity of description, the specific working processes of the systems, devices and units described above may be referred to the corresponding processes in the foregoing method embodiments, and will not be described again here.

The above are only some embodiments of the present disclosure, but the protection scope of the present disclosure is not limited thereto. Changes or replacements within the technical scope disclosed in the present disclosure easily thought of by those skilled in the art are covered by the protection scope of the present disclosure. Therefore, the protection scope of the present disclosure should be subject to the protection scope of the claims.

What is claimed is:

1. A positioning method, comprising:
sending, by a first device, measurement information; and
receiving, by the first device, location information of the first device, wherein the location information is obtained by processing the measurement information based on a positioning model.

2. The method according to claim 1, wherein the positioning model is a model corresponding to a positioning scenario where the first device is located.

3. The method according to claim 1, further comprising:
detecting, by the first device, first signals, wherein the first signals comprise a reference signal for positioning.

4. The method according to claim 3, wherein the first signals comprise first signals sent by K second devices.

5. The method according to claim 1, wherein the measurement information comprises at least one of the following:
time domain channel information;
frequency domain channel information; and
measurement indication information.

6. The method according to claim 1, further comprising:
receiving, by the first device, a first indication, wherein the first indication is configured to indicate relevant parameters of measurement information that the first device needs to feedback.

7. The method according to claim 1, further comprising:
receiving, by the first device, a second indication, wherein the second indication is configured to indicate channel measurement configuration for the first device.

8. The method according to claim 7, further comprising:
performing, by the first device, channel measurement based on the measurement configuration information, in response to receiving the second indication; and
feeding back, by the first device, measurement information and location information of the first device based on a model interface corresponding to a positioning scenario;
wherein the second indication further comprises a positioning model update indication and/or a positioning model training indication.

9. A positioning method, comprising:
receiving, by the second device, measurement information;
processing, by the second device, the measurement information based on a positioning model to obtain location information of the first device; and
sending, by the second device, the location information of the first device.

10. The method according to claim 9, further comprising:
sending, by the second device, first signals, wherein the first signals comprise a reference signal for positioning.

11. The method according to claim 9, further comprising:
sending, by the second device, a first indication, wherein the first indication is configured to indicate relevant parameters of the measurement information that the first device needs to feedback.

12. The method according to claim 9, further comprising:
sending, by the second device, a second indication, wherein the second indication is configured to indicate channel measurement configuration for the first device.

13. The method according to claim 12, further comprising:
receiving, by the second device, the measurement information fed back by the first device based on the model interface corresponding to the positioning scenario and the location information of the first device.

14. The method according to claim 12, wherein the second indication comprises a positioning model update indication and/or a positioning model training indication.

15. The method according to claim 12 further comprising:
constructing, by the second device, measurement information and location information fed back by multiple first devices into a sample data set; and
transfer training the first model by adopting the sample data set to obtain the second model.

16. The method according to claim 15, wherein the transfer training comprises:
adjusting a specific layer of the first model, wherein the specific layer comprises one or more layers adjacent to an output layer of the first model;
wherein the first model is an initial model, and the second model is a model after transfer training; or
the first model is a model after a previous transfer training, and the second model is an updated model after the present transfer training.

17. A first device, comprising: a processor and a memory, wherein the memory is configured to store a computer program, the processor is configured to call and run the computer program stored in the memory to execute:
sending, by a first device, measurement information; and
receiving, by the first device, location information of the first device, wherein the location information is obtained by processing the measurement information based on a positioning model.

18. The first device according to claim 17, wherein the processor is further configured to execute:
detecting, by the first device, first signals, wherein the first signals comprise a reference signal for positioning;
wherein the first signals comprise first signals sent by K second devices.

19. The first device according to claim 17, wherein the processor is further configured to execute:
receiving, by the first device, a first indication, wherein the first indication is configured to indicate relevant parameters of measurement information that the first device needs to feedback.

20. The first device according to claim 17, wherein the processor is further configured to execute:
receiving, by the first device, a second indication, wherein the second indication is configured to indicate channel measurement configuration for the first device;
performing, by the first device, channel measurement based on the measurement configuration information, in response to receiving the second indication; and
feeding back, by the first device, measurement information and location information of the first device based on a model interface corresponding to a positioning scenario;
wherein the second indication further comprises a positioning model update indication and/or a positioning model training indication.
